(19) United States
(12) Patent Application Publication
(10) Pub. No.: US 2026/0032917 A1
(43) Pub. Date: Jan. 29, 2026

(54) METHODS OF FORMING FERROELECTRIC DEVICES WITH METAL OXIDE SIDEWALL SPACERS

(71) Applicant: Tokyo Electron Limited, Tokyo (JP)

(72) Inventor: Sara Otsuki, Albany, NY (US)

(21) Appl. No.: 18/784,018

(22) Filed: Jul. 25, 2024

(51) Int. Cl. H10B 53/30; H10B 51/20; H10B 51/30; H10B 63/00

(52) U.S. Cl. CPC H10B 53/30; H10B 51/20; H10B 51/30; H10B 63/00

(57) ABSTRACT

A method of forming an electronic device includes forming a patterned stack including a first electrode layer deposited over a substrate, a ferroelectric material layer disposed over the first electrode layer, and a hard mask layer disposed over the ferroelectric material layer; forming a sidewall spacer along a sidewall of the patterned stack, the sidewall spacer including a metal oxide; etching the sidewall spacer selectively relative to the hard mask layer to expose a portion of a sidewall of the ferroelectric material layer; and depositing a second electrode layer over the ferroelectric material layer after removing the hard mask layer.

### TECHNICAL FIELD

The present invention relates generally to electronic devices, and, in particular embodiments, to electronic devices incorporating ferroelectric materials and methods for manufacturing the same.

### BACKGROUND

Unlike conventional dielectrics, ferroelectric materials possess a characteristic net electrical polarization—the remanent polarization, Pᵣ-even in the absence of an electric field E. When a sufficiently strong field is applied in opposition to Pᵣ, the polarization state of the ferroelectric switches, and the ferroelectric retains polarization −Pᵣ once the field is removed. As a result, ferroelectric materials fulfill the basic criteria for constructing nonvolatile memory by providing a physical implementation of a bit (two distinct polarization states) that does not require refreshing.

Because ferroelectrics also typically have high dielectric constants (low capacitance equivalent thicknesses, CETs), they are attractive materials for the design and fabrication of compact, low-power devices. Replacing conventional dielectrics with ferroelectrics yields ferroelectric random-access memory (FeRAM), ferroelectric tunnel junctions (FTJs), and ferroelectric field-effect transistors (FeFETs), among other conceivable devices. Ferroelectrics may not only serve as a drop—in replacement for conventional dielectrics, but their unique electrical properties may substantially improve the performance of some devices. For example, FTJs have giant tunneling resistances modulated by the ferroelectric polarization state, with OFF/ON resistance ratios as high as 10⁴.

The principal barrier to wider adoption of ferroelectric devices in commercial products, and specifically for memory devices, is an asymmetry in their read-write properties: Ferroelectric memories have nearly unlimited durability to read operations, but they exhibit relatively rapid fatigue and eventual breakdown when written. Fatigue in ferroelectrics is characterized by incremental reductions in the magnitude of Pᵣ that eventually compromise the distinguishability of the polarization states and lead to soft errors. In some instances, fatigue may measurably affect device properties (such as threshold voltages in a FeFET) within as few as 10³ read-write cycles. As such, there is significant interest in improving the durability of ferroelectric devices.

### SUMMARY

A method of forming an electronic device includes forming a patterned stack including a first electrode layer deposited over a substrate, a ferroelectric material layer disposed over the first electrode layer, and a hard mask layer disposed over the ferroelectric material layer; forming a sidewall spacer along a sidewall of the patterned stack, the sidewall spacer including a metal oxide; etching the sidewall spacer selectively relative to the hard mask layer to expose a portion of a sidewall of the ferroelectric material layer; and depositing a second electrode layer over the ferroelectric material layer after removing the hard mask layer.

An electronic device includes a first electrode layer; a ferroelectric material layer over the first electrode layer, the ferroelectric material layer including a first metal; a sidewall spacer flanking the first electrode layer and the ferroelectric material layer, the sidewall spacer including a metal oxide; and a second electrode layer.

A method of forming an electronic device includes depositing a layer stack including oxide layers and nitride layers over a substrate; forming a channel hole through the layer stack, further forming sidewalls of the layer stack; depositing a metal oxide layer along the sidewalls; depositing a ferroelectric material layer over the metal oxide layer; depositing a semiconducting channel layer over the ferroelectric material layer; and replacing the nitride layers and adjacent portions of the metal oxide layer with a gate material.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 provides a table of Gibbs energies of formation per metal atom at 0° C. for a selection of main-group and transition-metal oxides;

FIG. 2 is a chart of the Gibbs energies tabulated in FIG. 1;

FIGS. 3A-3M illustrate cross-sectional views of the formation of a ferroelectric capacitor with a sidewall spacer, in accordance with various embodiments;

FIGS. 4A-4M provide complementary top-down views of the formation of a ferroelectric capacitor with a sidewall spacer, in accordance with various embodiments;

FIG. 5 depicts a portion of a three-dimensional (3D) NAND flash memory, in accordance with an embodiment;

FIGS. 6A-6K illustrate cross-sectional views of the formation of a memory device with metal-oxide regions proximate to a ferroelectric material deposited in a channel hole of the memory device, in accordance with various embodiments, wherein FIGS. 6A-6I illustrate process steps forming a stack of alternating oxide and nitride layers adjacent to a channel hole filled with a metal oxide layer, a ferroelectric material layer, a semiconducting channel layer, and an isolation layer; wherein FIG. 6Ja illustrates removal of nitride layers that (in some embodiments) may result from a first step in a stepwise etch; wherein FIG. 6Jb illustrates the formation of openings for gates that (in the same embodiments depicted in FIG. 6Ja) may result from a second step in a stepwise etch or (in other embodiments) may follow FIG. 6I directly after a continuous etching process; and wherein FIG. 6K illustrates formation of the gates;

FIG. 7 is a flow chart for a method of forming an electronic device, and in particular for forming a ferroelectric capacitor with a sidewall spacer, in accordance with embodiments; and

FIG. 8 is a flow chart for a method of forming an electronic device, and in particular for forming a memory device with metal-oxide regions proximate to a ferroelectric material deposited in a channel hole of the memory device, in accordance with embodiments.

### DETAILED DESCRIPTION OF ILLUSTRATIVE EMBODIMENTS

Pristine ferroelectric materials often have a small remanent polarization that grows over repeated read-write cycling, a phenomenon called “wake-up.” With continued use, Pᵣ may reach a peak and then begin to decrease again, signaling the onset of fatigue. Fatigue eventually comes to an end when the device breaks down entirely.

Wake-up, fatigue, and breakdown stem from the same microscopic origin, namely, a field-modulated aging or ripening of the structure of the ferroelectric. These phenomena may be explained with reference to a specific ferroelectric material, such as hafnium zirconium oxide (HZO).

HZO materials have a continuum of possible formulas HfₓZr₁₋ₓO₂ (0≤x≤1), with HfO₂ (hafnia, x=1) and other hafnium-rich compositions being conventional dielectrics; compositions with x≈0.5 (i.e., near-equal amounts of hafnium and zirconium) being ferroelectric; and zirconium-rich compositions and ZrO₂ (zirconia, x=0) being antiferroelectric, with a vanishing polarization at zero field. The properties of HZO may be tuned both by the choice of x and by doping with metals (such as aluminum, silicon, or lanthanum) or non-metals (such as hydrogen, carbon, or nitrogen).

Ferroelectricity and antiferroelectricity in these latter HZO compositions originate in a bistability of their crystal structures. Two different arrangements of oxygens relative to the metal atoms are energetically equivalent in the absence of an electric field. When a field is applied, however, partial charges on each atom interact with the electric field to break this energetic symmetry, and one or the other arrangement (and the corresponding sign of a local dipole) will be preferred. In ferroelectric materials, domains in which the local dipoles are aligned predominate, leading to a net polarization; in antiferroelectrics, the local dipoles tend to alternate sign, leading to negligible bulk polarization (while preserving a high dielectric constant).

Even when prepared with careful attention to composition, HZO films typically comprise a mixture of grains corresponding to three distinct phases: an antiferroelectric tetragonal (t) phase, a ferroelectric orthorhombic (o) phase, and a paraelectric monoclinic (m) phase. (Paraelectric materials have nonlinear polarization behavior when a field is applied but no remanent polarization and no microscopic ordering of local dipoles, and thus are of no use for memory.) The t- and o-phases interconvert relatively freely, with the o-phase being slightly preferred for grains of larger size. Both t- and o-phases are significantly less stable than the m-phase as grains grow, but a large activation barrier tends to suppress interconversion—at least, as long as energy is not introduced into the system in the form of elevated temperatures or fields. In other words, read-write cycles provide energy that facilitates conversion of the t-phase to the o-phase and (ultimately) to the m-phase, degrading the ferroelectric properties of the HZO material.

HZO films may be deposited and annealed over (or while capped by) an electrode material with an incommensurate structure, such as tungsten or titanium nitride, which generates a strain favoring the formation of grains of the t- and o-phases. With repeated read-write cycling, the (initially relatively small) grains may fuse, and larger grains of the t-phase may convert to the o-phase. Both processes tend to make a film more uniformly ferroelectric and to increase the remanent polarization. While some grains of the o-phase may also convert irrecoverably to the paraelectric m-phase, there will be a net improvement in device properties during this wake-up period.

As cycling continues, the t-phase may be exhausted, and o-phase grains may further convert to the m-phase. At some point, the net effect of these processes will be to reduce the remanent polarization irreversibly, if only little by little. This fatigue period continues until the device breaks down.

In addition to varying numbers and sizes of t-, o-, and m-phase grains, an HZO film may also initially have a deposition process-determined concentration of defects, particularly oxygen vacancies with a +2 charge (Vo²⁺). The presence of these vacancies encourages the formation of t-phase grains when HZO films are deposited, extending the wake-up period. For this reason, and in accordance with various embodiments, HZO films may be deposited by a process such as atomic layer deposition (ALD) with a timed dose of an oxidant, such as water, which tends to increase the concentration of vacancies.

Over many read-write cycles, however, oxygen vacancies are believed to be the cause of breakdown. Like other types of defect, Vo²⁺ accumulates at grain boundaries within a film and at its surface. As the film ages and grains of the stable m phase grow, Vo²⁺ may form a continuous path from one surface of the film to the other along m-phase grain boundaries, forming a leakage path that shorts the device.

Embodiments of the present invention may enable the production of ferroelectric devices with a better write endurance by supplying oxygen to fill vacancies in the working ferroelectric. Filling vacancies continually may enable greater use of oxidants when depositing ferroelectrics, increasing the relative proportion of t-phase grains and extending the wake-up period, while also forestalling device breakdown by preventing the formation of leakage paths.

Oxygen cannot be safely or practicably supplied from an external source (such as a gas cylinder) to all of the ferroelectric components packaged within a finished chip. Rather, reservoirs of oxygen—in the form of oxygen-containing materials—may be disposed adjacent to the ferroelectric material layers and configured to supply oxygen to them as needed. A further advantage arises from placing oxygen reservoirs in the form of a sidewall spacer that abuts the ferroelectric without being incorporated into the device stack. Because of this separation, improvements to the durability of existing FeRAM, FTJ, and FeFET devices may be achieved without entailing a lengthy redesign process to account for changes in CETs and other design specifications.

The microscopic description of every Vo²⁺ will be somewhat different, and so too may be the mechanism by which it is filled. The details may be of interest, but mostly as a matter of fundamental scientific inquiry. For embodiments of the present invention, and in other practical contexts, all that may be desired is a reasonable heuristic for selecting oxygen-containing materials to pair with a given ferroelectric.

Filling one or more oxygen vacancies may be understood as an oxidation-reduction (redox) reaction between a metal in the ferroelectric and an oxygen-supplying partner. A generic example of such a redox reaction is the formation of a binary metal oxide from the bare metal and elemental oxygen:

$$mM ( s ) + \frac{n}{2} {O}_{2} ( g ) \to {M}_{m} {O}_{n} ( s ) \qquad ( Equation 1 )$$

Assuming that the oxide in question does not contain superoxide, peroxide, or ozonide anions though they may be accounted for if need be—the metal (initially with oxidation number, or ON, 0) reacts with oxygen gas (also ON 0) to yield a metal oxide (the metal within the oxide having ON+2n/m, relatively oxidized). The corresponding oxidation half-reaction is simply

$$M \to {M}^{+ 2 n / m} + \frac{2 n}{m} {e}^{-} \qquad ( Equation 2 )$$

Consequently, the thermodynamics of reactions in the form of Equation 1 may be used to assess the relative affinities of different metals for oxygen. The standard electrode potentials of half-reactions in the form of Equation 2 (albeit reversed, according to convention) may be used to assess the relative tendencies of different metals to be oxidized (or reduced). In various embodiments, such assessments (by pairwise comparison, ranking, or some other method) may form the basis for a heuristic choice of oxygen-containing material to supply oxygen to the ferroelectric. In other embodiments, additional mechanistic and kinetic factors may be considered; in still other embodiments, thermodynamics, kinetics, and mechanism may be used to provide a rigorous, global assessment of the oxygen-supplying capabilities of a given oxide when paired with a ferroelectric of interest.

For the thermodynamic heuristic based on Equation 1, and in various embodiments, it may be convenient to use the corresponding Gibbs energy of formation, ΔG_{f}, which is negative for spontaneous reactions. Gibbs energies are typically tabulated for compounds in their standard states, typically at 1 bar pressure and at 25° C., and reported in kcal/mol or kJ/mol; such values are denoted with a plimsoll symbol or degree symbol in the superscript, ΔG_{f}^{θ} or ΔG_{f}°. Because Gibbs energies, enthalpies, and entropies are state functions, these quantities may be combined for known reactions to obtain the corresponding values for reactions of interest not otherwise tabulated, in accordance with Hess's laws for thermochemistry.

The Gibbs energy has form ΔG_{f}=ΔH_{f}−TΔS_{f}, where ΔH_{f} is the enthalpy of formation, ΔS_{f}, is the entropy of formation, and T is the absolute temperature in K. Because Equation 1 involves a net loss of gas, ΔS_{f} will generally be negative, and the entropic contribution—TΔS_{f} will generally be positive. Accordingly, the spontaneity of the reaction will be determined in the first instance by the enthalpy, with negative enthalpies being required for spontaneity. Even assuming a negative enthalpy, the entropic contribution may become important at higher temperatures, with the reaction no longer being spontaneous above T_{eq}=(ΔH_{f}/ΔS_{f}). Therefore, in other embodiments, and especially at lower temperatures, the thermodynamic heuristic may instead be based on the enthalpy of formation.

An oxide OxA will tend to transfer oxygen to a bare metal M with corresponding oxide OxB if it has a more positive or rather less negative Gibbs energy, ΔG_{f}(OxA)>ΔG_{f}(OxB). The greater the difference between the two Gibbs energies, the greater the thermodynamic driving force will be for OxA to make the transfer. Analogous reasoning applies when comparing enthalpies, and also when comparing the standard electrode potentials E° (in volts) appropriate for use with Equation 2.

Standard electrode potentials are tabulated for individual atoms undergoing reduction, and thus directly provide information about the tendency of any given single atom with a certain ON to be reduced. By contrast, the Gibbs energies and enthalpies reflect the thermodynamics of forming oxide molecules that may comprise multiple atoms of one or more metals. That being the case, an additional thermodynamic heuristic may be obtained by normalizing the Gibbs energies or enthalpies of formation by the oxides' respective total numbers of metal atoms. For example, an oxide OxA comprising 3 metal atoms may have a Gibbs energy per metal atom ΔG̅_{f}(OxA) (ΔG_{f}(OxA)/3). Comparing ΔG_{f}(OxA) with ΔG_{f}(OxB) indicates the relative affinity of an average metal atom in each oxide for oxygen; as before, OxA will tend to transfer oxygen to an average bare metal atom of OxB when ΔG̅_{f}(OxA)>ΔG̅_{f}(OxB).

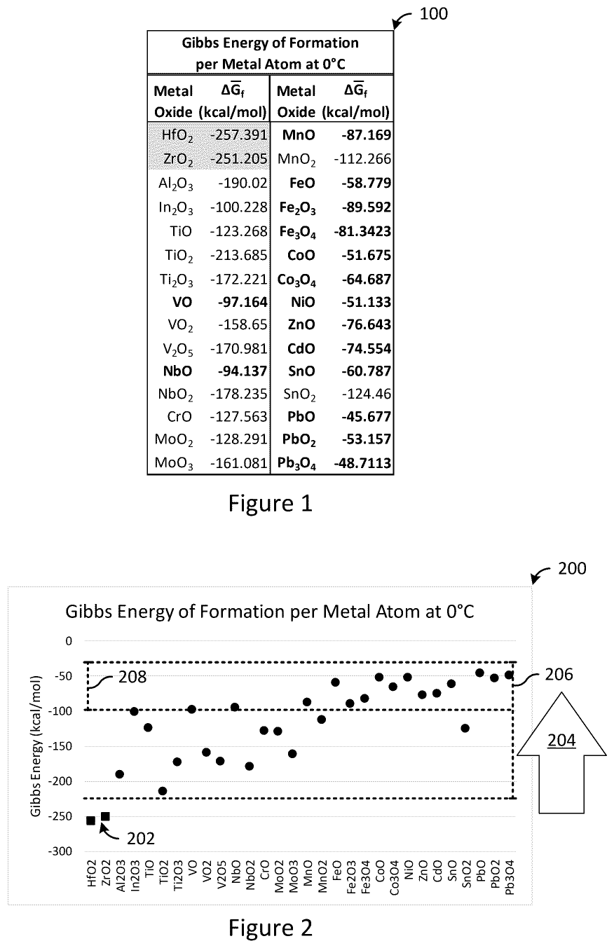

With that reasoning in mind, FIG. 1 provides a table 100 of Gibbs energies of formation per metal atom at 0° C. for a selection of binary metal oxides with generic chemical formula MₘOₘ. (The standard Gibbs energies may be somewhat less negative due to the entropic term, but any change will not be dramatic.) The oxides tabulated include both main-group (p-block) and transition-metal (d-block) oxides, with the ONs of the metals varying between +2 (e.g., TiO and other compounds with m=n=1) and +6 (MoO₃). A small number of mixed oxides with formula M₃O₄ are also included; in these compounds, one metal atom has an ON of +2 and the others have an ON of +3.

The table 100 includes the Gibbs energies for hafnia and zirconia as baseline references for the case of HZO. (The Gibbs energy for HZO itself may be approximated by a linear interpolation between the respective values, although a modest additional entropic contribution may enter due to the mixing of three elements. Note, however, that the non-stoichiometric nature of HZO means that the normalization per atom of the Gibbs energy does not change.) The other oxides tabulated have less negative Gibbs energies of formation, meaning that they will all have a propensity to provide oxygen to HZO, and that propensity may increase with the difference in Gibbs energies.

FIG. 2 provides a plot 200 of the Gibbs energies tabulated in the table 100, with the reference points 202 for hafnia and zirconia indicated. The (non-reference) Gibbs energies are plotted in order of an aufbau progression from the p block to the d block, with oxides of all compounds within a group presented in order from lowest to highest atomic number. A general trend toward less negative Gibbs energy (less spontaneous oxidation) is apparent, perhaps even tending to plateau near −45 kcal/mol. The later d-block oxides will therefore be more likely (in a heuristic, thermodynamic sense) to provide oxygen to HZO, as indicated by a large arrow 204. In some embodiments incorporating HZO ferroelectrics, appropriate oxygen-supplying materials may be metal oxides with Gibbs energy of formation per metal atom at 0° C. between −220 kcal/mol and −40 kcal/mol, as indicated by the interval and half-dashed lines 206. In some embodiments incorporating a ferroelectric oxide with standard Gibbs energy of formation per metal atom less than 0, appropriate oxygen-supplying materials may be metal oxides with standard Gibbs energy of formation per metal atom between 15% and 85% of that for the ferroelectric oxide.

Taken together, the table 100 and the plot 200 are intended to illustrate a sample of candidate oxygen-supplying materials, without excluding other possibilities. As long as a Gibbs energy comparison between a given oxide and a ferroelectric of interest indicates that the oxide may supply oxygen to the ferroelectric, and as long as material costs and complexity of integration are not prohibitive, oxygen-supplying materials may comprise more than one metal; a rare-earth (f-block) metal, a metalloid, or even a nonmetal; a metal with an arbitrarily high positive oxidation state; metal atoms with two or more differing oxidation states; oxygenic anions other than oxide, such as superoxide O²⁻, peroxide O₂²⁻, or ozonide O³⁻; or any other oxygen-containing compound.

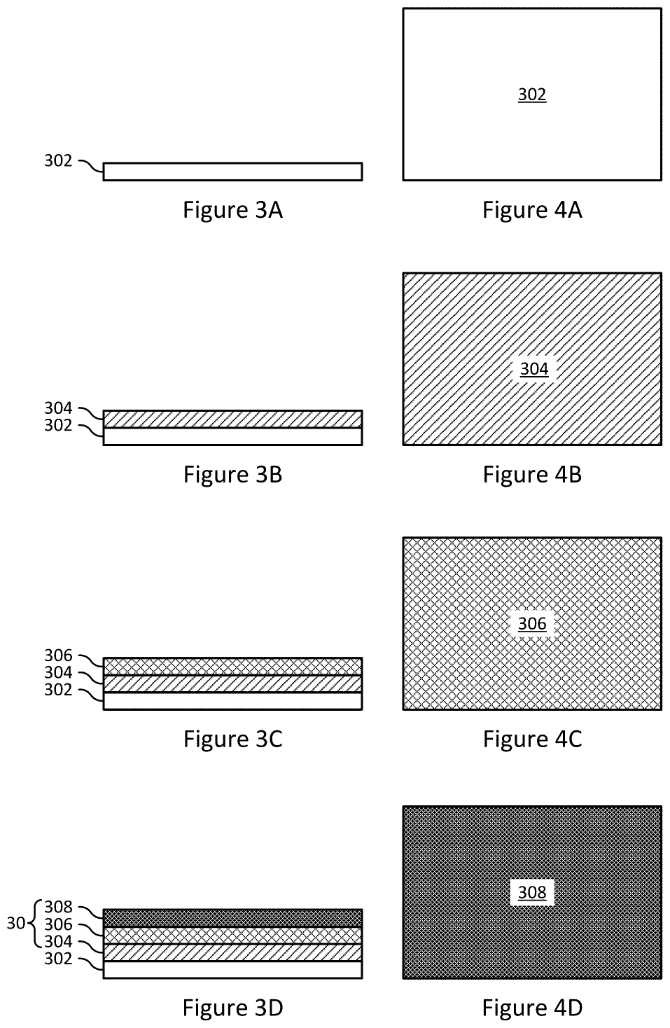

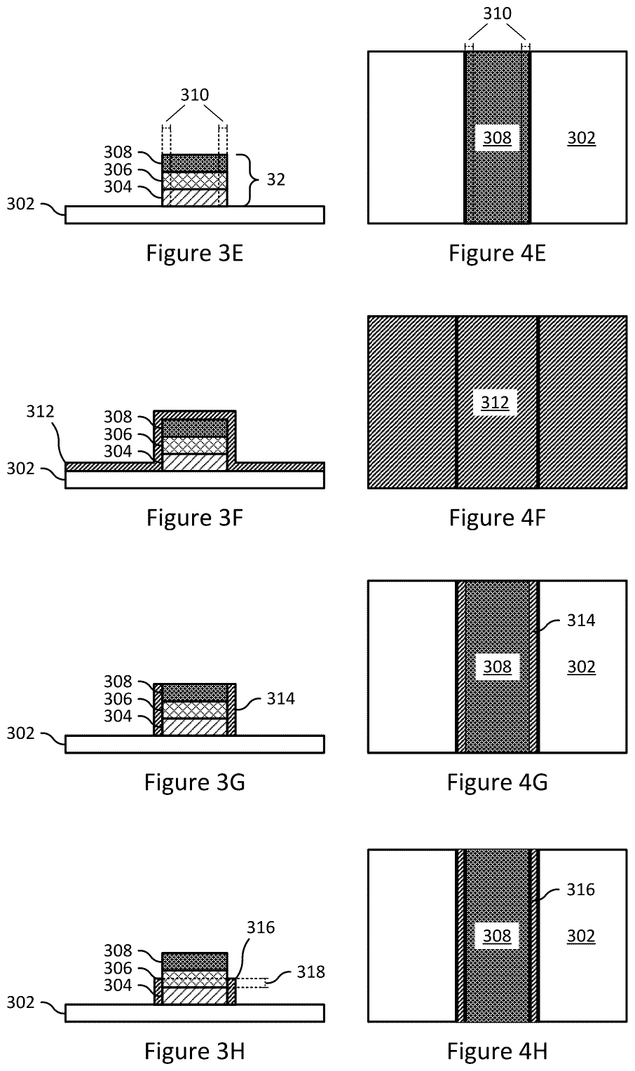

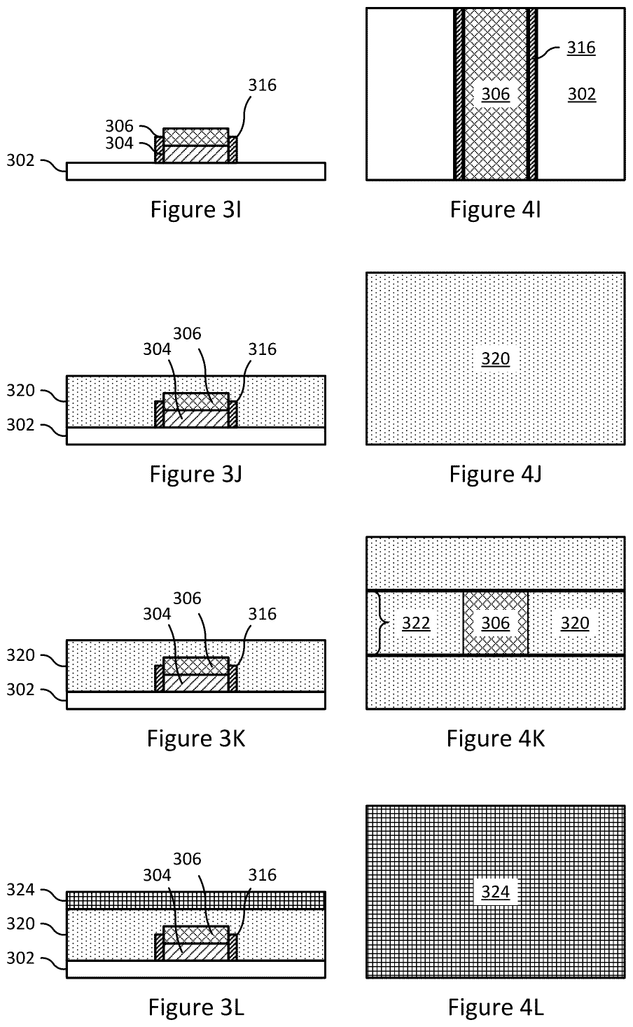

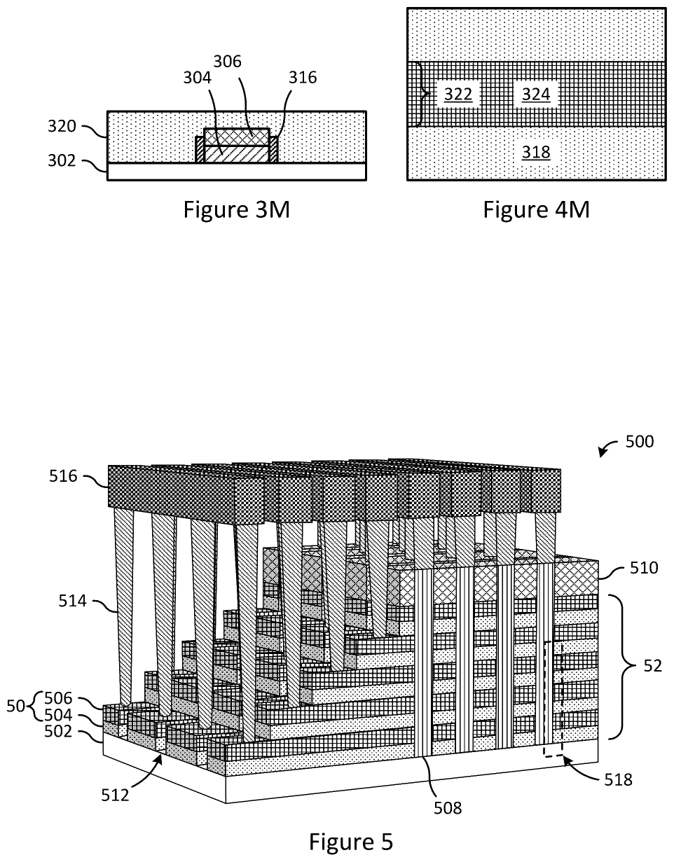

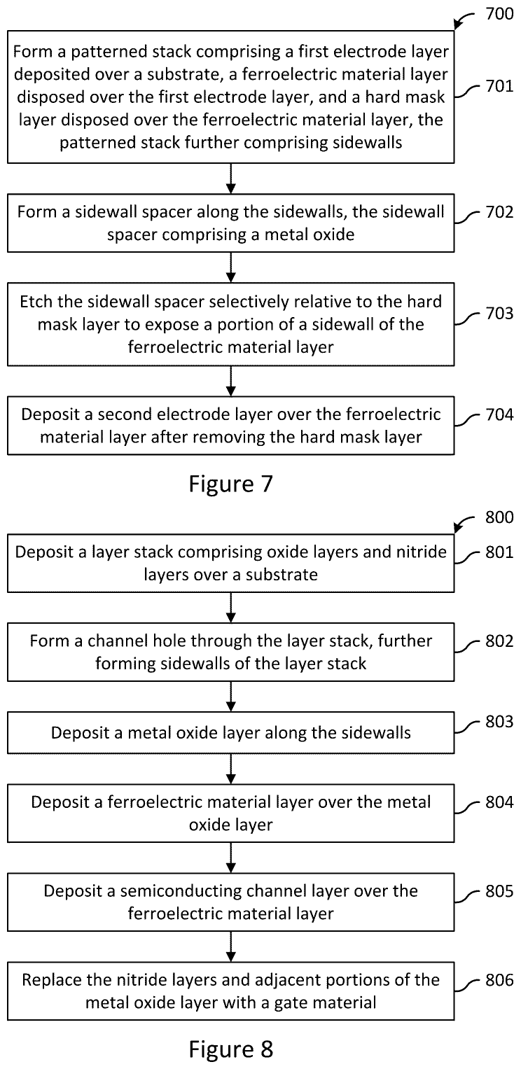

Given a choice of metal oxide suitably configured to supply oxygen to a chosen ferroelectric, the metal oxide may be incorporated into a device. FIGS. 3A-3M and 4A-4M respectively depict cross-sectional and top-down views of the formation of a ferroelectric capacitor with a sidewall spacer, in accordance with embodiments of the present application. (Like reference numerals are used to refer to identical features in the two figures.) In describing these figures, reference will also be made to FIG. 7, which is a flow chart of a method 700 underlying the illustrated steps.

FIGS. 3A and 4A depict a substrate 302, representing generically any suitable semiconductor workpiece being processed in accordance with embodiments of the present invention. The substrate 302 may be a bulk substrate such as a blank silicon wafer, a silicon-on-insulator (SOI) wafer, or any of various other semiconductor substrates. The substrate 302 may also be coated or layered with any number of additional materials, including compound semiconductors, metal or metalloid oxides, or metal or metalloid nitrides. The substrate 302 may include any material portion or structure of a device, particularly a semiconductor or other electronics device. Similarly, in some embodiments, the substrate 302 may itself be patterned or embedded in other components of a semiconductor structure or device.

With reference to FIGS. 3B and 4B, a first electrode layer 304 may be deposited over the substrate 302. The first electrode layer 304 may comprise any suitable conductive material, including elemental metals such as nickel, platinum, iridium, ruthenium, or tungsten; conductive nitrides such as titanium nitride or tantalum nitride; or conductive oxides such as iridium(IV) oxide, ruthenium(IV) oxide, lanthanum strontium cobalt oxide (LSCO), strontium ruthenium oxide (SRO), or lanthanum-doped SRO, according to various embodiments. The first electrode layer 304 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; or any other layer deposition process or combination thereof.

With reference to FIGS. 3C and 4C, a ferroelectric material layer 306 may be deposited over the first electrode layer 304. The ferroelectric material layer 306 may comprise hafnium zirconium oxide (HZO), in some embodiments. In other embodiments, the ferroelectric material layer 306 may comprise a perovskite, such as lithium niobate, barium titanate, bismuth ferrite, lead zirconium titanate (PZT), or lead magnesium niobate-lead titanate (PMN-PT); a layered perovskite such as strontium bismuth tantalate; a wurtzite, such as aluminum scandium nitride, aluminum boron nitride, or zinc magnesium oxide; or another ferroelectric compound, such as indium(III) selenide. The ferroelectric material layer 306 may be deposited using any suitable deposition technique, such as atomic layer deposition (ALD), physical vapor deposition (PVD), chemical vapor deposition (CVD), sol-gel deposition, or pulsed laser deposition (PLD).

For example, in an ALD process for HZO, alternating pulses of hafnium and zirconium precursors may be introduced into the reaction chamber, typically at temperatures between 200° C. and 400° C. and at low pressures, e.g., between 0.1 and 1 torr. Each precursor pulse may be followed by a purge step to remove excess precursors and byproducts; after the precursor pulses, an oxidant pulse introduces oxygen to oxidize the metal surface, followed by a further purge step to remove organics or other byproducts from the surface. Precursors may include hafnium tetrachloride (HfCl₄) or a metal-organic compound like tetrakis(ethylmethylamido)hafnium(IV) (TEMAH) for hafnium and zirconium tetrachloride (ZrCl₄) or a metal-organic compound like tetrakis(ethylmethylamido)zirconium(IV) (TEMAZ) for zirconium. Water vapor or ozone may be used as the oxidant.

Because each ALD cycle deposits a sub-monolayer of material, the ALD cycles is repeated until the desired thickness of the HZO film is achieved. The composition of the HZO film may be controlled by adjusting the number, length, and other parameters of the hafnium and zirconium precursor pulses. The thickness of the resulting ferroelectric material layer 306 may be between 2 nm and 20 nm, according to various embodiments.

With reference to FIGS. 3D and 4D, a hard mask layer 308 may be deposited over the ferroelectric material layer 306. The hard mask layer may comprise any suitable hard mask material, such as silicon nitride, titanium nitride, or silicon oxide. The hard mask layer 308 may be deposited using any suitable deposition technique, such as those enumerated above. The first electrode layer 304, the ferroelectric material layer 306, and the hard mask layer 308 collectively form an unpatterned stack 30.

With reference to FIGS. 3E and 4E, the hard mask layer 308 may be patterned and etched using any suitable lithography technique, such as dry lithography (e.g., using 193-nanometer dry lithography), immersion lithography (e.g., using 193-nanometer immersion lithography), i-line lithography (e.g., using 365-nanometer wavelength UV radiation for exposure), H-line lithography (e.g., using 405-nanometer wavelength UV radiation for exposure), extreme UV (EUV) lithography, or deep UV (DUV) lithography, in combination with any anisotropic etching method, such as reactive ion etching, to form a patterned stack 32. The width of the patterned stack 32 (i.e., its critical dimension) may be between 30 nm and 300 nm, according to various embodiments. In one embodiment, the critical dimension of the patterned stack 32 may be between 30 nm and 60 nm.

As indicated by intervals and half-dashed lines, the patterned stack 32 comprises sidewalls 310, alongside which sidewall spacers 314 may be formed. Consequently, FIGS. 3A-3E and 4A-4E illustrate a first step 701 of the method 700, according to various embodiments.

In some embodiments, the sidewall spacers 314 may be formed in two steps, as illustrated in FIGS. 3F-3G and 4F-4G. First, a metal oxide layer 312 may be deposited conformally over the patterned stack 32. The metal oxide layer 312 may be deposited using any suitable deposition technique, such as those enumerated above. The thickness of the metal oxide layer 312 may be between 2 nm and 20 nm, according to various embodiments. Second, the metal oxide layer 312 may be etched by any suitable anisotropic etching method, such as reactive ion etching, to form sidewall spacers 314. (FIGS. 3F-3G and 4F-4G thus illustrate a second step 702 of the method 700, according to various embodiments.) The width of the sidewall spacers 314 (i.e., their critical dimension) may be between 2 nm and 20 nm, according to various embodiments.

In some embodiments, it may be desirable to pattern the metal oxide layer 312 with photoresist prior to etching, such that only one of the sidewall spacers 314 is formed. The presence of two sidewall spacers 314 flanking the patterned stack 32 in FIGS. 3F-3M is not intended to exclude such embodiments.

The metal oxide layer 312, and thus the sidewall spacers 314 formed from it, may comprise any of a variety of metal oxides configured to supply oxygen to the ferroelectric material layer 306. In some embodiments, the metal oxide layer 312 may comprise a metal having a lower affinity for oxygen than the ferroelectric material layer 306 (or a constituent metal thereof). In various embodiments, relative oxygen affinities may be assessed according to one or more criteria described above, such as by comparisons of Gibbs energies of formation or electrochemical reduction potentials, whether in standard or non-standard states. In certain embodiments comprising an HZO ferroelectric, the metal oxide layer 312 may comprise a metal oxide having a Gibbs energy of formation per metal atom at 0° C. between −220 kcal/mol and −40 kcal/mol, such as those metal oxides tabulated in FIG. 1 and indicated by the interval and dashed lines 206 in FIG. 2. In other such embodiments, the metal oxide layer 312 may comprise a metal oxide having a Gibbs energy of formation per metal atom at 0° C. between −100 kcal/mol and −40 kcal/mol, such as those metal oxides tabulated in bold type in FIG. 1 and indicated by the smaller interval and dashed lines 208 in FIG. 2.

In some embodiments incorporating ferroelectric oxides with standard Gibbs energy of formation per metal atom less than 0, appropriate oxygen-supplying materials may be metal oxides with standard Gibbs energy of formation per metal atom between 15% and 85% of that for the ferroelectric oxide. In other embodiments, the metal oxides may have standard Gibbs energy of formation per metal atom between 15% and 60% of that for the ferroelectric oxide.

The metal oxide layer 312, and thus the sidewall spacers 314 formed from it, may comprise a main-group metal or a transition metal. In some embodiments, the metal oxide layer 312 may comprise a binary compound of a transition metal and oxygen (i.e., a compound with chemical formula MₓO_{y} for arbitrary values of the subscripts x and y). In other embodiments, the metal oxide layer 312 may comprise a transition metal in the +2 oxidation state, such that the corresponding compound may be an oxide MO, a mixed oxide such as M₃O₄ (not excluding other mixed stoichiometries), a peroxide M(II)O₂, a superoxide M(II)(O₂)₂, or an ozonide M(II)(O₃)₂. In certain embodiments, the metal oxide may comprise a transition metal such as vanadium, manganese, cobalt, nickel, zinc, niobium, or tin. In still other embodiments, the metal oxide layer may comprise ternary (M^{(a)}ₓM^{(b)}_{y}O_{z}), quaternary (M^{(a)}ₓM^{(b)}_{y}M^{(c)}_{z}O_{w}), or higher metal oxides of a set of metals {M^{(a)}, M^{(b)}, M^{(c)}, . . . }.

With reference to FIGS. 3H and 4H, the sidewall spacers 314 may be etched selectively relative to the hard mask layer 308 to form etched spacers 316 by any suitable etching method, such as reactive ion etching. The etched spacers 316 may be in contact with the sidewalls 310 (see FIGS. 3E and 4E) of the first electrode layer 304 and a lower portion 318 of the ferroelectric material layer 306, as indicated by the interval and half-dashed lines in FIG. 3H. (FIG. 3H thus illustrates a third step 703 of the method 700, according to various embodiments.) The lower portion 318 of the ferroelectric material layer 306 in contact with the etched spacers 316 may cover 30% to 70% of the sidewalls of the ferroelectric material layer 306, according to various embodiments. In an embodiment, etched spacers 316 cover half of the sidewalls by extending up to half the thickness of the ferroelectric material layer 306.

The hard mask layer 308 may be removed by any suitable etching method, such as a wet etch or a reactive ion etch, as depicted in FIGS. 3I and 4I.

FIGS. 3J-3M and 4J-4M illustrate one possible approach to completing the ferroelectric capacitor, namely, a single damascene process yielding a device in crosspoint configuration, in accordance with various embodiments. (Together with FIGS. 3I and 4I, FIGS. 3J-3M and 4J-4M thus illustrate a fourth step 704 of the method 700.) Such a device may be part of a linear or planar array of similar devices, as may be suitable for these embodiments.

In other embodiments not illustrated here, a second electrode layer may be disposed between the ferroelectric material layer 306 and the hard mask layer 308, i.e., deposited in an interstitial step between FIGS. 3C-3D and FIGS. 4C-4D. Formation of the sidewall spacers 314, as described with reference to FIGS. 3E-3F and FIGS. 4E-4F, and etching to yield etched spacers 316, as described with reference to FIGS. 3G and 4G, may then follow, resulting in a complete device stack with collinear geometry flanked by the etched spacers 316.

Irrespective of how the device may be finished, the lack of physical contact between the etched spacers 316 and a second electrode layer 324 (see for example FIGS. 3M and 4M), combined with the interposition of a pre-metallization dielectric 320, is a further advantage of the embodiments. Barring the incorporation in various embodiments of a secondary source of oxygen from which to replenish the etched spacers 316, only a finite amount of oxygen may be delivered from the etched spacers 316 to the ferroelectric material layer 306. As the metal oxide of the etched spacers 316 continually supplies oxygen to the ferroelectric material layer 306, the etched spacers 316 may also comprise an increasing proportion of partially reduced or bare metal, which may conduct some current from the first electrode layer 304 during operation. The physical separation between the etched spacers 316 and the second electrode layer 324 ensures that the etched spacers 316 may not themselves form a leakage path to short the device.

With continuing reference to FIGS. 3J and 4J, the pre-metallization dielectric 320 may be deposited over the ferroelectric material layer 306, the etched spacers 316, and the substrate 302. The pre-metallization dielectric 320 may comprise silicon oxide or other suitable materials, including low-k dielectric materials, according to various embodiments. The pre-metallization dielectric 320 may be deposited using any suitable deposition technique, such as those enumerated above. In an embodiment, the pre-metallization dielectric 320 may be silicon oxide deposited by metal-organic CVD using tetraethyl orthosilicate (TEOS).

With reference to FIGS. 3K and 4K, the pre-metallization dielectric 320 may be patterned by any suitable lithographic process and etched by any dry etching method, such as reactive ion etching, to form a trench 322, as indicated by the bracket in FIG. 4K. According to various embodiments, the width of the trench 322 may be between 20 nm and 500 nm and the depth of the trench 322 may be between 5 nm and 100 nm, such that a corresponding portion of an upper surface of the ferroelectric material layer 306 is exposed.

With reference to FIGS. 3L and 4L, the second electrode layer 324 may be deposited in the trench 322 and over the pre-metallization dielectric 320 using any suitable deposition technique, such as those enumerated above. The second electrode layer 324 may comprise any suitable conductive material, including elemental metals such as nickel, platinum, iridium, ruthenium, or tungsten; conductive nitrides such as titanium nitride or tantalum nitride; or conductive oxides such as iridium(IV) oxide, ruthenium(IV) oxide, lanthanum strontium cobalt oxide (LSCO), strontium ruthenium oxide (SRO), or lanthanum-doped SRO, according to various embodiments. The second electrode layer 324 may be deposited using any suitable deposition technique, such as those enumerated above. The thickness of the second electrode layer 324 may be between 5 nm and 100 nm, according to various embodiments, with a minimum thickness determined by the depth of the trench 322.

With reference to FIGS. 3M and 4M, any portion of the second electrode layer 324 outside of the trench 322 may be removed and the pre-metallization dielectric 320 may be planarized by chemical-mechanical planarization, according to various embodiments. As described above, in certain embodiments, the completed ferroelectric capacitor of FIGS. 3M and 4M may form one component of a linear or planar array in crosspoint configuration. Devices incorporating the completed ferroelectric capacitor of FIGS. 3M and 4M may include, according to various embodiments, FeRAM, FTJs, FeFETs, ferroelectric content-addressable memories (FeCAMs), including ferroelectric ternary CAMs (FeTCAMs), artificial synapses for neuromorphic computing (such as reservoir computing), and other such devices.

Other embodiments of the present invention enable the production of memory devices, such as a 3D NAND flash memory 500 of the type partially illustrated in FIG. 5. In 3D NAND flash memories, word plates 50 comprising alternating oxide layers 504 and gates 506 are disposed over a substrate 502 to form a memory stack 52. The substrate 502 may be a substrate in the sense described above, and may further comprise lower structures of the 3D NAND flash memory 500, such as a source plate and a bottom selector plate comprising source-end select gates. An uppermost word plate of the memory stack 52 may be covered, in various embodiments, with a cap layer 510 comprising a dielectric material over upper structures of the 3D NAND flash memory 500, such as a top selector plate comprising drain-end select gates.

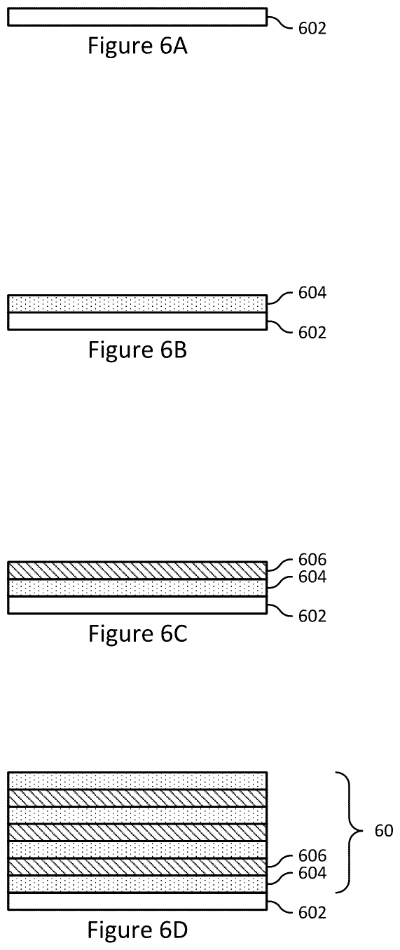

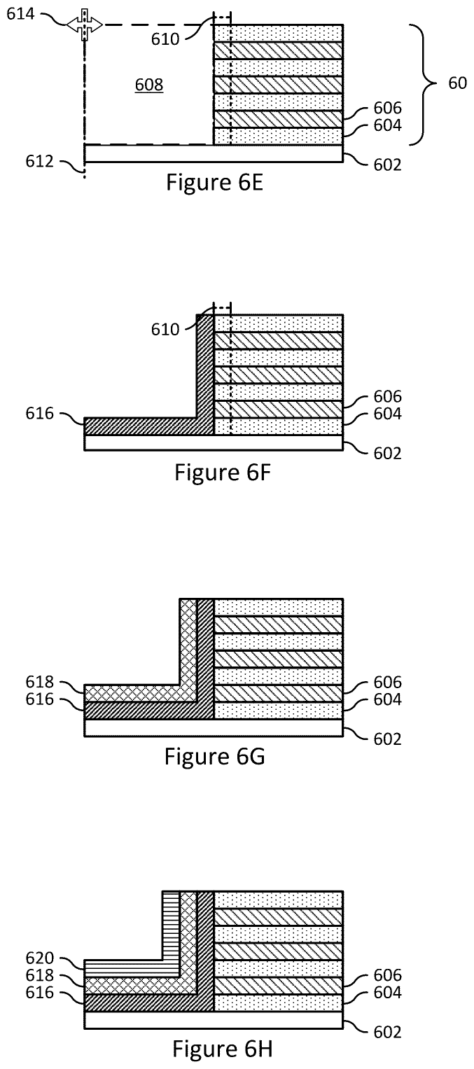

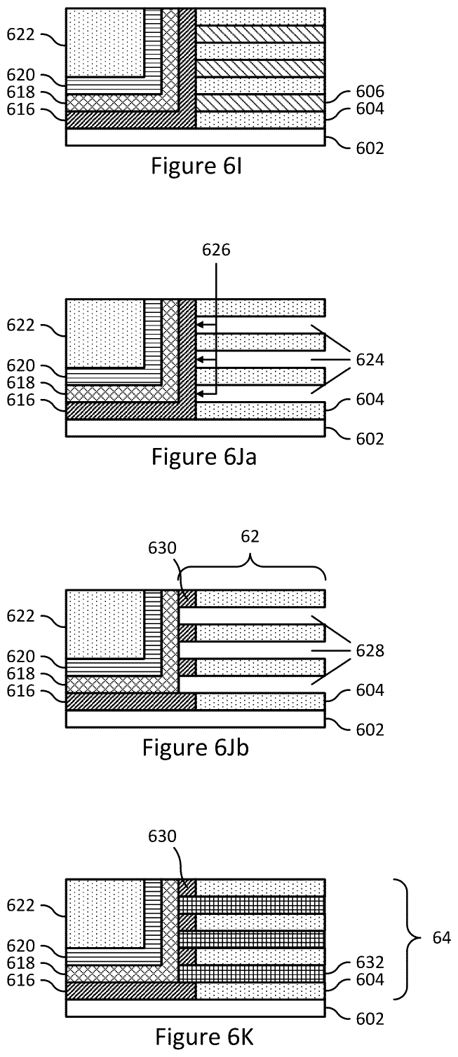

During fabrication, nitride layers 606 (see, for example, FIG. 6D) may occupy the spaces subsequently filled by the gates 506, in particular while memory channels 508 are patterned and etched; the memory stack 52 is subjected to a staircase etch (providing direct access to each of the word plates 50 for eventual metallization); and word isolation slits 512 are formed (creating separately addressable word lines). The memory channels 508 are subsequently filled with the capacitive, ferroelectric, and conductive materials implementing the memory bits and connecting them to the rest of the 3D NAND flash memory 500. Nitride layers 606 are typically then replaced with gates 506 (also 632, with specific reference to FIG. 6K), followed by formation of the cap layer 510; the contacts 514; and the bit lines 516.

The present application, in various embodiments, enables the formation of 3D NAND flash memory devices with improved durability and comparable device characteristics by incorporating a metal oxide layer adjacent and/or physically contacting the ferroelectric. FIGS. 6A-6K illustrate cross-sectional views of the formation of such a memory device, in accordance with various embodiments. A corresponding region of the 3D NAND flash memory 500 depicted in FIG. 5 is indicated by the half-dashed area 518. Note, however, that the aspect ratio implied by FIG. 5 has not been preserved in FIGS. 6A-6K and that the intention is to illustrate clearly the composition and relative positioning of the various layers, rather than to present them to scale. In describing these figures, reference will also be made to FIG. 8, which is a flow chart of a method 800 underlying the illustrated steps.

FIG. 6A depicts a substrate 602, representing generically any suitable semiconductor workpiece being processed in accordance with embodiments. The substrate 602 may be a substrate in the sense described above; in particular, and consistent with the discussion of FIG. 5, the substrate 602 may include lower structures of the 3D NAND flash memory 500, such as a source plate and a bottom-select plate comprising source-end select gates.

With reference to FIG. 6B, an oxide layer 604 may first be deposited using any suitable deposition technique, such as PVD by sputtering, evaporation, or molecular beam evaporation; PLD, ALD, or CVD; plasma-enhanced CVD or ALD; metal-organic, low-pressure, or rapid thermal CVD; or any other layer deposition process or combination thereof. In an embodiment, the oxide layer 604 may be silicon oxide deposited by metal-organic CVD using tetraethyl orthosilicate (TEOS).

With reference to FIG. 6C, a nitride layer 606 may then be deposited using any suitable deposition technique, such as those enumerated above. In an embodiment, the nitride layer 606 may comprise silicon nitride.

Deposition of alternating oxide and nitride layers may be repeated indefinitely, until (with reference to FIG. 6D) a layer stack 60 of a target depth has been formed. (Taken together, FIGS. 6A-6D thus illustrate a first step 801 of the method 800, according to various embodiments.) While the layer stack 60 is depicted as comprising four oxide layers 604 and three nitride layers 606, these small numbers have been chosen merely for purposes of illustration and should not be construed as limiting. Indeed, the layer stack 60 may comprise dozens of such layers, according to various embodiments.

The layer stack 60 having been deposited, a channel hole 608 may be formed through the layer stack 60, as illustrated in FIG. 6E. The channel hole 608 may be formed by any suitable anisotropic etching method, such as reactive ion etching. Portions of the layer stack 60 thus exposed and directly proximate to the channel hole 608 comprise sidewalls 610 of the layer stack, as indicated by the interval and half-half-dashed lines in FIG. 6E. Consequently, FIG. 6E illustrates a second step 802 of the method 800, according to various embodiments.

Except in embodiments with the channel hole 608 disposed at an outer edge of the layer stack 60, formation of the channel hole 608 will form a pair of sidewalls 610 of the layer stack 60. (To be precise, a pair of sidewalls 610 may be apparent in cross-section, even if the channel hole 608 has a continuous cross section when viewed from above, as may be true for embodiments forming gate-all-around memory devices.) FIGS. 6E-6K illustrate remaining steps 803-806 of the method 800 for sidewalls 610 at the “right” of the channel hole 608, relative to the chosen cross-sectional view, but these figures should not be construed to imply that similar processes may not occur at the “left” of the channel 608. Indeed, for a vast majority of embodiments, a full representation of the formation and subsequent filling of the channel hole 608 may be obtained by mirroring FIGS. 6E-6K across an axis 612 passing vertically through the leftmost edge of the respective figures, as indicated by a left-right arrow block 614 in FIG. 6E. In other words, the channel hole 608 may be flanked by alternating oxide layers 604 and nitride layers 606, according to various embodiments (and consistent with the depiction in FIG. 5).

With reference to FIG. 6F, a metal oxide layer 616 may be deposited along the sidewalls 610 and over the substrate 602 using any suitable deposition technique, such as PVD by sputtering, evaporation, or molecular beam evaporation; PLD, ALD, or CVD; plasma-enhanced CVD or ALD; metal-organic, low-pressure, or rapid thermal CVD; or any other layer deposition process or combination thereof. FIG. 6F illustrates a third step 803 of the method 800.

With reference to FIG. 6G, a ferroelectric material layer 618 may be deposited over the metal oxide layer 616 using any suitable deposition technique, such as PVD by sputtering, evaporation, or molecular beam evaporation; PLD, ALD, or CVD; plasma-enhanced CVD or ALD; metal-organic, low-pressure, or rapid thermal CVD; or any other layer deposition process or combination thereof. FIG. 6G illustrates a fourth step 804 of the method 800.

With reference to FIG. 6H, a semiconducting channel layer 620 may be deposited over the ferroelectric material layer 618 using any suitable deposition technique, such as PVD by sputtering, evaporation, or molecular beam evaporation; PLD, ALD, or CVD; plasma-enhanced CVD or ALD; metal-organic, low-pressure, or rapid thermal CVD; or any other layer deposition process or combination thereof. The semiconducting channel layer 620 may comprise polycrystalline silicon, in some embodiments; in other embodiments, the semiconducting channel layer 620 may comprise other semiconductor materials such as amorphous silicon, silicon germanium, and indium gallium zinc oxide. FIG. 6H illustrates a fifth step 805 of the method 800.

Optionally, whether before or after the steps depicted in FIGS. 6J-6K, an isolation layer 622 may be deposited over the semiconducting channel layer 620 using any suitable deposition technique, such as PVD by sputtering, evaporation, or molecular beam evaporation; PLD, ALD, or CVD; plasma-enhanced CVD or ALD; metal-organic, low-pressure, or rapid thermal CVD; or any other layer deposition process or combination thereof, as illustrated in FIG. 6I. In some embodiments, the isolation layer 622 may comprise silicon oxide deposited by metal-organic CVD using tetraethyl orthosilicate (TEOS). Deposition of the isolation layer 622 may serve, according to some embodiments forming a 3D trench NAND memory device, to separate the “left” and “right” sides of the channel hole and form two memory devices in the same volume, by contrast with a gate-all-around structure of the type illustrated in FIG. 5.

Although not shown in the process flow of FIGS. 6A-6K, additional holes may be formed in the layer stack 60 in order to allow process chemicals to reach the buried nitride layers 606. If the staircase etch yielding the stacked word plates 50 has been performed, the additional holes may be the contact holes eventually to be metallized to form the contacts 514 of FIG. 5; in other case, the additional holes may be adjacent channel holes within the same word line not yet filled as per FIGS. 6E-6I. Irrespective of how the nitride layers 606 are exhumed, the fabrication process may continue according to either of two possibilities described below:

In some embodiments, and with reference to FIGS. 61 and 6Ja, it may be possible to remove the nitride layers 606 and adjacent portions of the metal oxide layer 626 in a single step, proceeding directly from FIG. 6I to FIG. 6Jb and yielding a hollowed stack 62 comprising oxide layers 604 and metal oxide pads 630 separated by openings 628. In some such embodiments, the nitride layers 606 and adjacent portions of the metal oxide layer 626 may be etched by a single wet etch chemistry. (One possible shared etch chemistry for use in a continuous process may be hot phosphoric acid.) In other such embodiments, the nitride layers 606 and adjacent portions of the metal oxide layer 626 may be etched by distinct wet etch chemistries that are compatible for simultaneous, continuous use. In these other embodiments, it may still be the case that the nitride layers 606 are etched by hot phosphoric acid. In the aforementioned embodiments and in others, wet etching may be timed to limit overetching of the metal oxide layer 616 and damage to the ferroelectric material layer 618.

In other embodiments, it may be that the nitride layers 606 and adjacent portions of the metal oxide layer 626 are etched in stepwise fashion, with a first etch chemistry being used to remove the nitride layers 606. After removing the nitride layers 606, nitride openings 624 may be formed, revealing adjacent portions of the metal oxide layer 626, as depicted in FIG. 6Ja. Subsequently, a second etch chemistry (different from the first) may be used to remove the adjacent portions of the metal oxide layer 626, yielding the structure depicted in FIG. 6Jb and already described above. In these other embodiments, it may still be the case that the first etch chemistry used to remove the nitride layers 606 may be hot phosphoric acid.

The openings 628 in the hollowed stack 62 may be flushed to remove any residual etchant and then filled with a gate material to form gates 632 and thus a completed device stack 64, as shown in FIG. 6K. (As such, FIGS. 6J-6K illustrate a sixth step 806 of the method 800, according to various embodiments.) The gate material may be deposited in the openings 628 using any suitable deposition technique, such as PVD by sputtering, evaporation, or molecular beam evaporation; PLD, ALD, or CVD; plasma-enhanced CVD or ALD; metal-organic, low-pressure, or rapid thermal CVD; or any other layer deposition process or combination thereof.

The method 800 of FIG. 8, as illustrated in FIGS. 6A-6K and in accordance with various embodiments, may be used to fabricate key components of the 3D NAND flash memory 500 of FIG. 5. In particular, the process just described may be used to form the word plates 50 and to fill each of the memory channels 508. In other embodiments, multiple devices of the type depicted in FIG. 5 may be stacked or otherwise connected in order to create a larger, composite memory.

Example embodiments of the invention are described below. Other embodiments can also be understood from the entirety of the specification as well as the claims filed herein.

Example 1. A method of forming an electronic device, the method including: forming a patterned stack including a first electrode layer deposited over a substrate, a ferroelectric material layer disposed over the first electrode layer, and a hard mask layer disposed over the ferroelectric material layer; forming a sidewall spacer along a sidewall of the patterned stack, the sidewall spacer including a metal oxide; etching the sidewall spacer selectively relative to the hard mask layer to expose a portion of a sidewall of the ferroelectric material layer; and depositing a second electrode layer over the ferroelectric material layer after removing the hard mask layer.

Example 2. The method of example 1, where forming the sidewall spacer includes: conformally depositing a metal oxide layer over the patterned stack; and anisotropically etching the metal oxide layer.

Example 3. The method of one of examples 1 or 2, where the metal oxide is configured to supply oxygen to the ferroelectric material layer.

Example 4. The method of one of examples 1 to 3, where the metal oxide includes a metal having a lower affinity for oxygen than the ferroelectric material layer.

Example 5. The method of one of examples 1 to 4, where the ferroelectric material layer includes a ferroelectric oxide having a first standard Gibbs energy of formation per metal atom with a first value less than 0, and where the metal oxide has a second standard Gibbs energy of formation per metal atom between 15% and 85% of the first value.

Example 6. The method of one of examples 1 to 5, where the ferroelectric material layer includes a ferroelectric oxide having a first standard Gibbs energy of formation per metal atom with a first value less than 0, and where the metal oxide has a second standard Gibbs energy of formation per metal atom between 15% and 60% of the first value.

Example 7. The method of one of examples 1 to 6, where the metal oxide includes a binary compound of a transition metal and oxygen.

Example 8. The method of one of examples 1 to 7, where the metal oxide includes a transition metal with a +2 oxidation number.

Example 9. The method of one of examples 1 to 8, where the metal oxide includes vanadium, manganese, iron, cobalt, nickel, zinc, niobium, or tin.

Example 10. An electronic device including: a first electrode layer; a ferroelectric material layer over the first electrode layer, the ferroelectric material layer including a first metal; a sidewall spacer flanking the first electrode layer and the ferroelectric material layer, the sidewall spacer including a metal oxide; and a second electrode layer.

Example 11. The electronic device of example 10, where the ferroelectric material layer includes a ferroelectric oxide having a first standard Gibbs energy of formation per metal atom with a first value less than 0, and where the metal oxide has a second standard Gibbs energy of formation per metal atom between 15% and 85% of the first value.

Example 12. The electronic device of one of examples 10 or 11, where the metal oxide has a Gibbs energy of formation per metal atom at 0° C. between −100 kcal/mol and −40 kcal/mol.

Example 13. The electronic device of one of examples 10 to 12, where the metal oxide includes a binary compound of a transition metal and oxygen.

Example 14. The electronic device of one of examples 10 to 13, where the metal oxide includes a transition metal with a +2 oxidation number.

Example 15. The electronic device of one of examples 10 to 14, where the metal oxide includes vanadium, manganese, iron, cobalt, nickel, zinc, niobium, or tin.

Example 16. The electronic device of one of examples 10 to 15, where the electronic device is part of a ferroelectric memory device, ferroelectric tunnel junction, or ferroelectric field-effect transistor.

Example 17. A method of forming an electronic device, the method including: depositing a layer stack including oxide layers and nitride layers over a substrate; forming a channel hole through the layer stack, further forming sidewalls of the layer stack; depositing a metal oxide layer along the sidewalls; depositing a ferroelectric material layer over the metal oxide layer; depositing a semiconducting channel layer over the ferroelectric material layer; and replacing the nitride layers and adjacent portions of the metal oxide layer with a gate material.

Example 18. The method of example 17, where replacing the nitride layers and adjacent portions of the metal oxide layer includes: etching the nitride layers to form openings in the layer stack and to expose the adjacent portions of the metal oxide layer; etching the adjacent portions of the metal oxide layer to expose the ferroelectric material layer; and depositing a plurality of gate layers in the openings in the layer stack, the plurality of gate layers being in contact with the ferroelectric material layer.

Example 19. The method of one of examples 17 or 18, where the nitride layers and the adjacent portions of the metal oxide layer are etched using a continuous etching process.

Example 20. The method of one of examples 17 to 19, where the continuous etching process includes etching with hot phosphoric acid.

Example 21. The method of one of examples 17 to 20, where the nitride layer is etched using a first etch chemistry, and the adjacent portions of the metal oxide layer are etched using a second etch chemistry different from the first etch chemistry.

Example 22. The method of one of examples 17 to 21, where the first etch chemistry includes hot phosphoric acid.

Example 23. The method of one of examples 17 to 22, where the metal oxide layer is configured to supply oxygen to the ferroelectric material layer.

Example 24. The method of one of examples 17 to 23, where the metal oxide layer includes a metal having a lower affinity for oxygen than the ferroelectric material layer.

Example 25. The method of one of examples 17 to 24, where the ferroelectric material layer includes a ferroelectric oxide having a first standard Gibbs energy of formation per metal atom with a first value less than 0, and where the metal oxide layer includes a metal oxide having a second standard Gibbs energy of formation per metal atom between 15% and 85% of the first value.

Example 26. The method of one of examples 17 to 25, where the metal oxide layer includes a binary compound of a transition metal and oxygen.

Example 27. The method of one of examples 17 to 26, where the metal oxide layer includes a transition metal with a +2 oxidation number.

Example 28. The method of one of examples 17 to 27, where the metal oxide layer includes vanadium, manganese, iron, cobalt, nickel, zinc, niobium, or tin.

Example 29. A memory device including: a layer stack including a plurality of gates, a plurality of oxide layers, and a plurality of metal oxide regions, each layer of the layer stack including either: one of the plurality of gates, or one of the plurality of oxide layers and one of the plurality of metal oxide regions; a channel hole disposed through the layer stack, the channel hole including sidewalls; a ferroelectric material layer disposed along a sidewall of the channel hole; and a semiconducting channel layer disposed over the ferroelectric material layer within the channel hole.

Example 30. The memory device of example 29, further including an isolation layer disposed over the semiconducting channel layer within the channel hole.

Example 31. The memory device of one of examples 29 or 30, where the semiconducting channel layer includes polycrystalline silicon.

Example 32. The memory device of one of examples 29 to 31, where the semiconducting channel layer includes indium gallium zinc oxide.

Example 33. The memory device of one of examples 29 to 32, where the plurality of metal oxide regions is configured to supply oxygen to the ferroelectric material layer.

Example 34. The memory device of one of examples 29 to 33, where the plurality of metal oxide regions includes a metal having a lower affinity for oxygen than the ferroelectric material layer.

Example 35. The memory device of one of examples 29 to 34, where the plurality of metal oxide regions includes a metal oxide, the metal oxide having a Gibbs energy of formation per metal atom at 0° C. between −100 kcal/mol and −40 kcal/mol.

Example 36. The memory device of one of examples 29 to 35, where the plurality of metal oxide regions includes a binary compound of a transition metal and oxygen.

Example 37. The memory device of one of examples 29 to 36, where the plurality of metal oxide regions includes a transition metal with a +2 oxidation number.

Example 38. The memory device of one of examples 29 to 37, where the plurality of metal oxide regions includes vanadium, manganese, iron, cobalt, nickel, zinc, niobium, or tin.

Example 39. The memory device of one of examples 29 to 38, where the memory device is part of a three-dimensional NAND flash memory.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming an electronic device, the method comprising:
forming a patterned stack comprising a first electrode layer deposited over a substrate, a ferroelectric material layer disposed over the first electrode layer, and a hard mask layer disposed over the ferroelectric material layer;
forming a sidewall spacer along a sidewall of the patterned stack, the sidewall spacer comprising a metal oxide;
etching the sidewall spacer selectively relative to the hard mask layer to expose a portion of a sidewall of the ferroelectric material layer; and
depositing a second electrode layer over the ferroelectric material layer after removing the hard mask layer.

2. The method of claim 1, wherein forming the sidewall spacer comprises:
conformally depositing a metal oxide layer over the patterned stack; and
anisotropically etching the metal oxide layer.

3. The method of claim 1, wherein the metal oxide comprises a metal having a lower affinity for oxygen than the ferroelectric material layer.

4. The method of claim 1, wherein the ferroelectric material layer comprises a ferroelectric oxide having a first standard Gibbs energy of formation per metal atom with a first value less than 0, and wherein the metal oxide has a second standard Gibbs energy of formation per metal atom between 15% and 85% of the first value.

5. The method of claim 1, wherein the metal oxide comprises a transition metal with a +2 oxidation number.

6. The method of claim 1, wherein the metal oxide comprises vanadium, manganese, iron, cobalt, nickel, zinc, niobium, or tin.

7. An electronic device comprising:
a first electrode layer;
a ferroelectric material layer over the first electrode layer, the ferroelectric material layer comprising a first metal;
a sidewall spacer flanking the first electrode layer and the ferroelectric material layer, the sidewall spacer comprising a metal oxide; and
a second electrode layer.

8. The electronic device of claim 7, wherein the ferroelectric material layer comprises a ferroelectric oxide having a first standard Gibbs energy of formation per metal atom with a first value less than 0, and wherein the metal oxide has a second standard Gibbs energy of formation per metal atom between 15% and 85% of the first value.

9. The electronic device of claim 7, wherein the metal oxide comprises vanadium, manganese, iron, cobalt, nickel, zinc, niobium, or tin.

10. The electronic device of claim 7, wherein the electronic device is part of a ferroelectric memory device, ferroelectric tunnel junction, or ferroelectric field-effect transistor.

11. A method of forming an electronic device, the method comprising:
depositing a layer stack comprising oxide layers and nitride layers over a substrate;
forming a channel hole through the layer stack, further forming sidewalls of the layer stack;
depositing a metal oxide layer along the sidewalls;
depositing a ferroelectric material layer over the metal oxide layer;
depositing a semiconducting channel layer over the ferroelectric material layer; and
replacing the nitride layers and adjacent portions of the metal oxide layer with a gate material.

12. The method of claim 11, wherein replacing the nitride layers and adjacent portions of the metal oxide layer comprises:
etching the nitride layers to form openings in the layer stack and to expose the adjacent portions of the metal oxide layer;
etching the adjacent portions of the metal oxide layer to expose the ferroelectric material layer; and
depositing a plurality of gate layers in the openings in the layer stack, the plurality of gate layers being in contact with the ferroelectric material layer.

13. The method of claim 12, wherein the nitride layers and the adjacent portions of the metal oxide layer are etched using a continuous etching process.

14. The method of claim 13, wherein the continuous etching process comprises etching with hot phosphoric acid.

15. The method of claim 12, wherein the nitride layer is etched using a first etch chemistry, and the adjacent portions of the metal oxide layer are etched using a second etch chemistry different from the first etch chemistry.

16. The method of claim 15, wherein the first etch chemistry comprises hot phosphoric acid.

17. The method of claim 11, wherein the metal oxide layer comprises a metal having a lower affinity for oxygen than the ferroelectric material layer.

18. The method of claim 11, wherein the ferroelectric material layer comprises a ferroelectric oxide having a first standard Gibbs energy of formation per metal atom with a first value less than 0, and wherein the metal oxide layer comprises a metal oxide having a second standard Gibbs energy of formation per metal atom between 15% and 85% of the first value.

19. The method of claim 11, wherein the metal oxide layer comprises a transition metal with a +2 oxidation number.

20. The method of claim 11, wherein the metal oxide layer comprises vanadium, manganese, iron, cobalt, nickel, zinc, niobium, or tin.
